(19) United States
(12) Patent Application Publication
(10) Pub. No.: US 2024/0206071 A1
(43) Pub. Date: Jun. 20, 2024

(54) SWITCHING POWER SUPPLY DEVICE

(71) Applicant: Murata Manufacturing Co., Ltd., Kyoto-fu (JP)

(72) Inventors: Tatsuya HOSOTANI, Nagaokakyo-shi (JP); Osamu MIKI, Nagaokakyo-shi (JP)

(73) Assignee: Murata Manufacturing Co., Ltd., Kyoto-fu (JP)

(21) Appl. No.: 18/587,254

(22) Filed: Feb. 26, 2024

Related U.S. Application Data
(63) Continuation of application No. PCT/JP2022/031556, filed on Aug. 22, 2022.

(30) Foreign Application Priority Data
Aug. 30, 2021 (JP) 2021-139811

(51) Int. Cl. H05K 1/16; H02M 3/00

(52) U.S. Cl. CPC H05K 1/165; H02M 3/003; H05K 1/162

(57) ABSTRACT

A switching power supply device includes a circuit board on which plural inductor windings are formed, and a common magnetic body incorporated into the circuit board from both sides. The circuit board has a common wiring line electrically connected to one end of each of the plural inductor windings in common. The common magnetic body has inner legs inserted through inside the plural inductor windings and an outer leg inserted through outside the plural inductor windings. A smoothing capacitor connected between a common wiring line and ground wiring is mounted on the circuit board to constitute a smoothing filter with the inductance of the common wiring line and the smoothing capacitor. The plural inductor windings are magnetically coupled to each other, and the common wiring line and the plural inductor windings are substantially not magnetically coupled.

### CROSS-REFERENCE TO RELATED APPLICATIONS

This application claims benefit of priority to International Patent Application No. PCT/JP2022/031556, filed Aug. 22, 2022, and to Japanese Patent Application No. 2021-139811, filed Aug. 30, 2021, the entire contents of each are incorporated herein by reference.

### BACKGROUND

### Technical Field

The present disclosure relates to a switching power supply device including a composite inductor composed of a plurality of inductors magnetically coupled to each other and a smoothing inductor that smooths the output current and output voltage.

### Background Art

In a switching power supply module that performs multi-phase operation, it is desirable to have a small ripple of the current flowing in the inductor and a good load response to realize high-speed load response. In a steady-state condition, a larger LC value in the output smoothing circuit reduces the ripple, but in a transient condition during load changes, a smaller LC value increases the response speed and improves the characteristics. Therefore, it is necessary to determine the LC value considering both the steady-state condition and the transient condition.

In recent years, the development of a coupling technology for magnetically coupling inductors to a multi-phase power supply has been intensified. By using the action of canceling the magnetic flux generated by the current flowing in one inductor with the magnetic flux generated by the current flowing in the other inductor, the inductors can be made smaller and the ripple current can be reduced. In particular, the greater the number of phases in the multi-phase power supply and the more inductors used, the greater the effect and impact.

As a composite inductor obtained by combining a plurality of inductors, U.S. Pat. No. 8,294,544 discloses a coupling inductor that adopts a structure in which each rung, which is a ladder-shaped cleat, has a conductor wound around it.

### SUMMARY

When using the ladder-shaped cores described in U.S. Pat. No. 8,294,544, the number of cores is increased horizontally or vertically when increasing the number of the inductors to be coupled, which makes the overall structure more complex. Since such a coupling inductor is mounted as a component on a circuit board to form a module, the module becomes taller after the coupling inductor is mounted. In addition, when using ladder-shaped cores, the winding structure becomes more complex as the number of the inductors to be coupled increases, thus increasing the assembly cost of the coupling inductor.

By providing a plurality of inductors, the ripple of the current flowing in each inductor can be reduced. On the other hand, the current ripple contained in the output current resulting from the merging of the currents flowing in the respective inductors and the voltage ripple superimposed on the output voltage are not reduced or, on the contrary, are increased due to the non-uniformity of the merged output current.

Therefore, the present disclosure provides a high-performance switching power supply device having excellent power integrity (power quality assurance). The switching power supply device includes a composite inductor which is composed of a plurality of inductors magnetically coupled with each other on a single circuit board to have a lower height and excellent coupling inductor performance and a smoothing inductor magnetically independent of the coupling inductors to have excellent smoothing inductor performance for reducing the current ripple included in the output current resulting from the merging of the currents in the respective inductors and the voltage ripple included in the output voltage.

A switching power supply device according to an example of the present disclosure includes a plurality of power conversion circuits including a composite inductor; and a control circuit for the power conversion circuits. The composite inductor includes a circuit board on which a plurality of inductor windings is formed and a common magnetic body incorporated into the circuit board. The circuit board has an electrical connection point with one end of each of the plurality of inductor windings as a common potential. A common wiring line is provided to electrically connect the electrical connection point and one side of an output terminal. The common magnetic body has inner legs each inserted through inside a respective one of the plurality of inductor windings and an outer leg inserted through outside the plurality of inductor windings. A smoothing capacitor is provided that is electrically connected between one side of the output terminals and the other side of the output terminals and is mounted on the circuit board. The inductance of the common wiring line and the smoothing capacitor constitute a smoothing filter. The plurality of inductor windings has a first magnetic coupling coefficient by the common magnetic body, and the common wiring line and the plurality of inductor windings have a second magnetic coupling coefficient. The absolute value of the first magnetic coupling coefficient is five or more times the absolute value of the second magnetic coupling coefficient.

According to the present disclosure, it is possible to obtain a high-performance switching power supply device which includes a composite inductor composed of a coupling inductor having a small size, lower height and excellent power conversion characteristics and a smoothing inductor having excellent smoothing characteristics for reducing output current ripple and output voltage ripple integrated by integration. The coupling inductor consists of a plurality of inductors magnetically coupled with each other on a single circuit board, wherein the magnetic fluxes generated by the currents flowing in the plurality of windings are cancelled with each other and the magnetic flux density distributed on magnetic bodies is reduced to suppress magnetic saturation. The switching power supply device can be made smaller and thinner, can achieve highly accurate output voltage and output voltage fluctuation suppression, and has excellent power integrity (power quality assurance).

### BRIEF DESCRIPTION OF THE DRAWINGS

FIG. 1 is a perspective view of a power supply module with a composite inductor according to a first embodiment;

FIG. 2 is a perspective view of a circuit board of the power supply module;

FIG. 3 is an exploded perspective view of the power supply module;

FIG. 4 is a circuit diagram of a multi-phase power supply device according to the first embodiment;

FIG. 5A is a waveform diagram of a current flowing in one inductor of the multi-phase power supply device, and FIG. 5B is a waveform diagram of a current flowing in one inductor of a multi-phase power supply device as a comparative example;

FIG. 6 shows a relationship between a current ripple and the ratio of a leakage inductance to a mutual inductance;

FIGS. 7A and 7B are partial sectional view of the power supply module, and FIG. 7C is a partial plan view of the power supply module;

FIGS. 8A, 8B, and 8C are partial sectional views and a partial plan view of a power supply module, which is different from the examples shown in FIGS. 7A, 7B, and 7C;

FIG. 9 is a partial sectional view of a power supply module, which is further different from the example shown in FIG. 8B;

FIG. 10 is an exploded perspective view of a power supply module according to a second embodiment;

FIG. 11 is an exploded perspective view of a power supply module according to a third embodiment;

FIG. 12 is a perspective view of a power supply module with a composite inductor according to a fourth embodiment;

FIG. 13 is a perspective view of a circuit board of the power supply module;

FIG. 14 is an exploded perspective view of the power supply module; and

FIG. 15 is a circuit diagram of a multi-phase power supply device according to the fourth embodiment.

### DETAILED DESCRIPTION

Several specific examples will be given below, with reference to the drawings, to describe a plurality of embodiments for implementing the present disclosure. The same reference sign is used in each drawing for the same part. For ease of explanation or understanding of the main points, the embodiment is divided into a plurality of embodiments for ease of explanation, the configurations described in the different embodiments can be partially substituted or combined. In the second and subsequent embodiments, descriptions of matters in common to the first embodiment are omitted, and only the points of difference are described. In particular, similar effects of similar configurations are not described sequentially for each embodiment.

<First Embodiment>

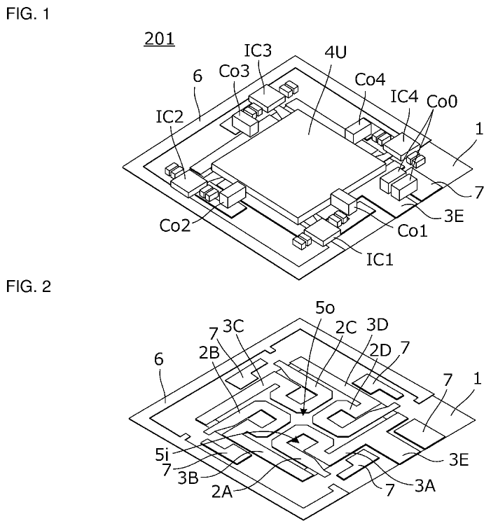

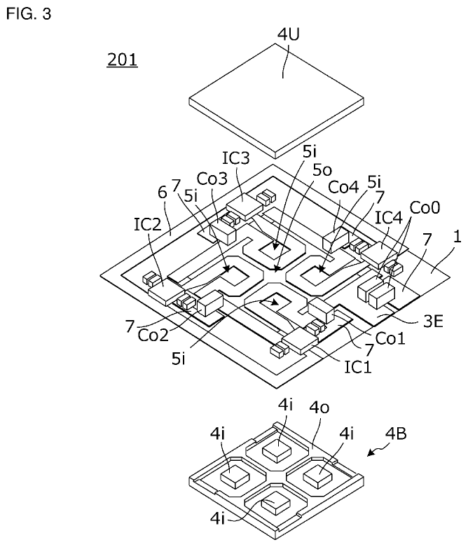

FIG. 1 is a perspective view of a power supply module 201 with a composite inductor according to a first embodiment. FIG. 2 is a perspective view of a circuit board of the power supply module 201. FIG. 3 is an exploded perspective view of the power supply module 201.

The power supply module 201 includes a circuit board 1, a plurality of components mounted on the circuit board 1, and a lower magnetic body 4B and an upper magnetic body 4U that are incorporated into the circuit board 1 from both sides. The lower magnetic body 4B and the upper magnetic body 4U constitute a “common magnetic body” according to the present disclosure.

As illustrated in FIG. 2, four inductor windings 2A, 2B, 2C, and 2D are formed in the circuit board 1. Further, common wiring lines 3A, 3B, 3C, 3D, and 3E are formed on the circuit board 1 to electrically connect one end of each of the plurality of inductor windings 2A, 2B, 2C, and 2D in common. Further, input power supply wiring 6 and ground wiring 7 are formed on the circuit board 1. The ground wiring 7 corresponds to the “reference potential wiring” of the present disclosure. The inductor windings 2A, 2B, 2C, and 2D and the common wiring lines 3A, 3B, 3C, and 3D are formed in a 90° rotational symmetry relationship along the surface of the circuit board 1.

The circuit board 1 is a multilayer circuit board, and the inductor windings 2A, 2B, 2C, and 2D have a plurality of layers of conductor patterns formed in the circuit board 1 and a plurality of via conductors that interconnect the plurality of layers of conductor patterns. Such a configuration reduces the parasitic resistance of the inductor windings 2A, 2B, 2C, and 2D, thus reducing the power loss.

As illustrated in FIG. 3, in the circuit board 1, each of the inductor windings 2A, 2B, 2C, and 2D has an opening 5i formed thereinside. Further, an opening 5o is formed outside the inductor windings 2A, 2B, 2C, and 2D. The upper surface of the lower magnetic body 4B has inner legs 4i each inserted through a respective one of the openings 5i, and an outer leg 4o inserted through the opening 5o. The lower surface of the upper magnetic body 4U has an outer leg 4o that is inserted through the opening 5o. The height of the outer leg 4o of the lower magnetic body 4B plus the height of the outer leg 4o of the upper magnetic body 4U equals the height of the inner leg 4i.

The lower magnetic body 4B and the upper magnetic body 4U are incorporated into the circuit board 1 from both sides with the circuit board 1 interposed therebetween. The lower magnetic body 4B and the upper magnetic body 4U are joined via an adhesive layer with a relative permeability of 1 or higher provided on the opposite surfaces of the lower magnetic body 4B and the upper magnetic body 4U. The adhesive layer with a relative permeability of 1 or higher is, for example, a solidified layer of an adhesive obtained by mixing magnetic powder such as ferrite powder or metal powder with a bonder.

The lower magnetic body 4B, the upper magnetic body 4U and the inductor windings 2A, 2B, 2C, and 2D constitute four inductors. Further, the common wiring line 3E constitutes an inductor. The inductor windings 2A, 2B, 2C, and 2D are magnetically coupled to each other by the lower magnetic body 4B and the upper magnetic body 4U, and the inductor composed of the common wiring line and the inductor windings 2A, 2B, 2C, and 2D are substantially not magnetically coupled.

The inductor windings 2A, 2B, 2C, and 2D are in a 90° rotational symmetry relationship along the surface of the circuit board 1, so that for each inductor the magnetic coupling relationship with the other inductors is equal. Such a configuration reduces the variation in inductance of each inductor.

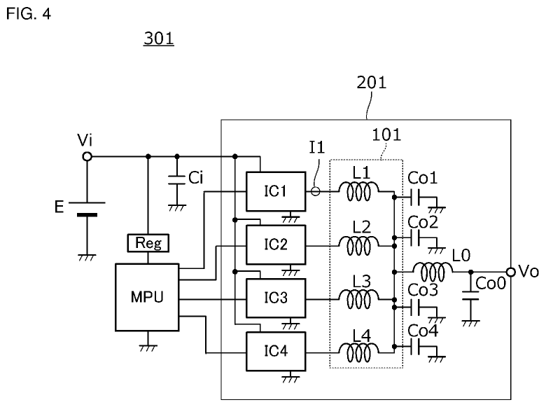

FIG. 4 is a circuit diagram of a multi-phase power supply device 301 according to the first embodiment. The multi-phase power supply device 301 is composed of the power supply module 201 and a control circuit for the power supply module 201. The power supply module 201 is mounted on a circuit board of an electronic device. The control circuit of the power supply module 201 is provided on the circuit board.

The multi-phase power supply device 301 connects an input power supply E with a voltage Vi to its input section and outputs an output voltage Vo from its output section.

The power supply module 201 includes switching integrated circuits IC1, IC2, IC3, and IC4, inductors L0, L1, L2, L3, and L4, and smoothing capacitors Co0, Co1, Co2, Co3, and Co4. The inductors L1, L2, L3, and L4 are composed of a composite inductor 101. The inductors L1, L2, L3, and L4 are composed of the inductor windings 2A, 2B, 2C, and 2D, the lower magnetic body 4B, and the upper magnetic body 4U. The switching integrated circuits IC1, IC2, IC3, and IC4 each have a high-side switching element and a low-side switching element.

The inductor L0 is composed of the common wiring line 3E. The inductance of the common wiring line 3E and the smoothing capacitors Co1, Co2, Co3, Co4, and Co0 constitute a π-type smoothing filter. The cut-off frequency of the smoothing filter is set equal to or higher than the switching frequency to effectively reduce ripple voltage and switching noise.

As illustrated in FIGS. 1 and 2, the switching integrated circuits IC1, IC2, IC3, and IC4, the smoothing capacitors Co0, Co1, Co2, Co3, and Co4, and the like are mounted on the circuit board 1. The smoothing capacitors Co1, Co2, Co3, and Co4 are connected between the common wiring lines 3A, 3B, 3C, and 3D and the ground wiring 7. Further, the smoothing capacitors Co1, Co2, Co3, and Co4 are connected between the ground wiring 7 and the vicinity of the connection portions between the inductor windings 2A, 2B, 2C, and 2D and the common wiring lines 3A, 3B, 3C, and 3D, respectively. The smoothing capacitor Co0 is connected between the common wiring line 3E and the ground wiring 7. Such a configuration makes it possible to reduce the parasitic inductance generated in the series in each of the smoothing capacitors Co1, Co2, Co3, Co4, and Co0 and increase the attenuation in the attenuation region of the frequency characteristic of the smoothing filter.

An MPU illustrated in FIG. 4 is the control circuit for the power supply module 201. The MPU receives a power supply voltage from the input power supply E through a register Reg. An input capacitor Ci smooths the input power supply voltage of the power supply module 201. The MPU provides multi-phase switching control signals to the switching integrated circuits IC1, IC2, IC3, and IC4. The switching integrated circuits IC1, IC2, IC3, and IC4 supply multi-phase (4-phase) currents to the inductors L1, L2, L3, and L4. The smoothing capacitors Co0, Co1, Co2, Co3, and Co4 smooth the output voltage Vo.

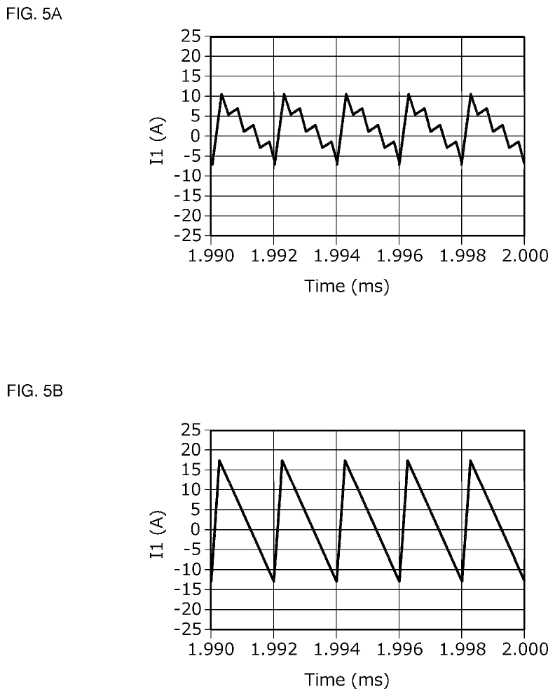

FIG. 5A is a waveform diagram of a current flowing in one inductor of the multi-phase power supply device 301. FIG. 5B is a waveform diagram of a current flowing in one inductor of a multi-phase power supply device as a comparative example. The conditions are as follows.
Vi: 12V
Vo: 1.8V
Switching frequency: 500 kHz
Total capacitance of smoothing capacitors: 400 μF
Output current: 8 A

Here, if a mutual inductance of the inductors L1, L2, L3, and L4 is expressed as Lm and a leakage inductance is expressed as Lk, then Lm/L =1 and Lm+Lk=0.1 μF in the multi-phase power supply device 301, and Lm=0 μF in the multi-phase power supply device as the comparative example.

As is clearly known by comparing FIGS. 5A and 5B, the ripple of the current flowing through each of the inductors L1, L2, L3, and L4 is suppressed by forming the inductors L1, L2, L3, and L4 with a composite inductor. In such an example, the current ripple is suppressed from 31A to 18A.

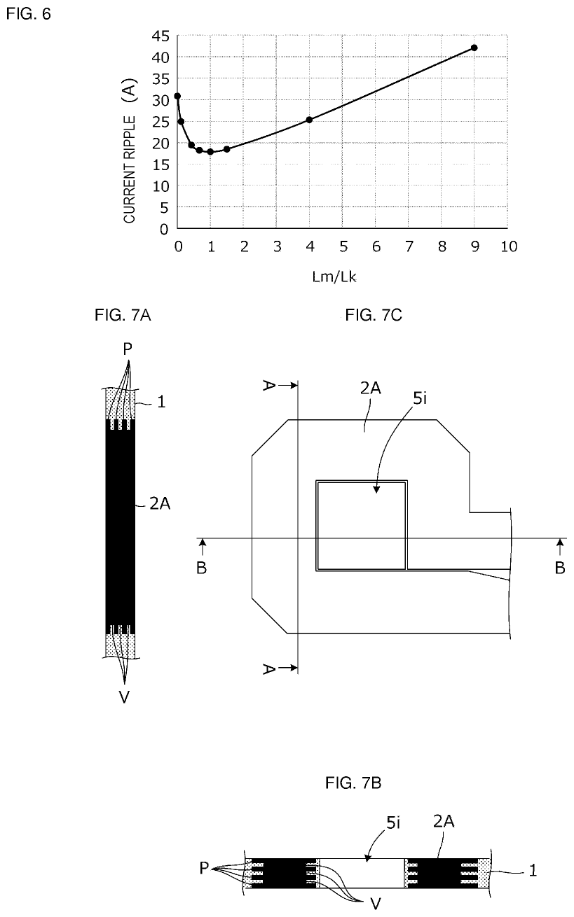

FIG. 6 shows a relationship between the current ripple and the ratio of the leakage inductance Lk to the mutual inductance Lm. As can be seen from the graph, the current ripple is lowest when Lm/Lk=1.

Some detailed structures of the above-described inductor windings will be described below by way of example. FIGS. 7A and 7B are partial sectional views of the power supply module 201, and FIG. 7C is a partial plan view of the power supply module 201. FIG. 7C illustrates only the inductor winding 2A, which is illustrated in FIGS. 2, 3, and the like. FIG. 7A is a sectional view of an A-A portion in FIG. 7C, and FIG. 7B is a sectional view of a B-B portion in FIG. 7C.

The inductor winding 2A includes a plurality of layers of conductor patterns P formed in the circuit board 1 and via conductors V that interconnect the plurality of layers of conductor patterns P.

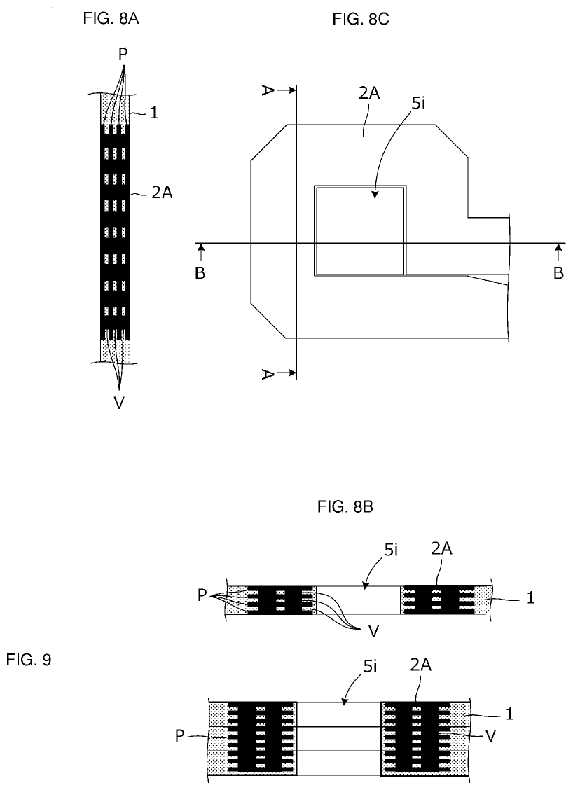

FIGS. 8A, 8B, and 8C are partial sectional views and a partial plan view of a power supply module 201, which is different from the example shown in FIGS. 7A, 7B, and 7C. FIGS. 8A and 8B are partial sectional views of the power supply module 201, and FIG. 8C is a partial plan view of the power supply module 201. FIG. 8C illustrates only the inductor winding 2A, which is illustrated in FIGS. 2, 3, and the like. FIG. 8A is a sectional view of an A-A portion in FIG. 8C, and FIG. 8B is a sectional view of a B-B portion in FIG. 8C.

The inductor winding 2A includes a plurality of layers of conductor patterns P formed in the circuit board 1 and via conductors V that interconnect the plurality of layers of conductor patterns P. In such an example, a plurality of via conductors are distributed in the plane direction. The conductor patterns P may be interconnected at a plurality of positions.

FIG. 9 is a partial sectional view of a power supply module 201, which is further different from the example illustrated in FIG. 8B. FIGS. 7B, 8B, and the like show examples where four layers of conductor patterns P are interconnected by three layers of via conductors V, while in the example shown in FIG. 9, nine layers of conductor patterns P are interconnected by eight layers of via conductors V. Thus, the number of layers of the conductor patterns may be further increased.

FIGS. 7A, 7B, 7C, 8A, 8B, 8C, and 9 show examples for the inductor winding 2A, but the same applies to other inductor windings.

### Second Embodiment

The second embodiment describes, by way of example, a power supply module that differs from the power supply module described in the first embodiment in the configurations of the common magnetic body and the opening.

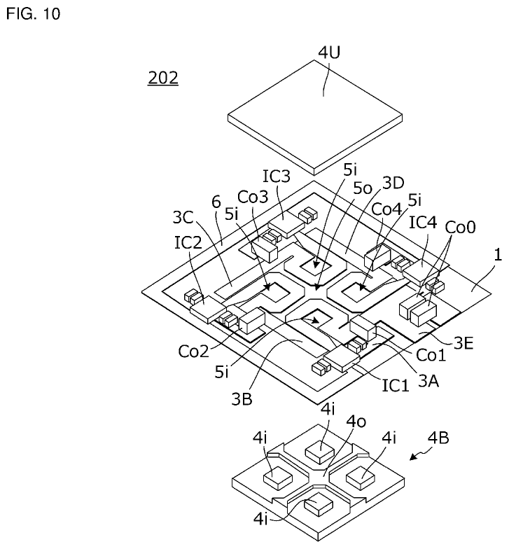

FIG. 10 is an exploded perspective view of a power supply module 202 according to the second embodiment. The power supply module 202 differs from the power supply module 201 illustrated in FIG. 3 in the first embodiment in the structures of the outer leg 4o and the opening 5o of the common magnetic body.

In the example shown in FIG. 3, the lower magnetic body 4B and the upper magnetic body 4U are each provided with the outer leg 4o surrounding the entire periphery of the inner legs 4i; however, in the second embodiment, a lower magnetic body 4B and an upper magnetic body 4U are each provided with an outer leg 4o shielding between mutually adjacent inner legs 4i. Other configurations are the same as those described in the first embodiment.

As described in the present embodiment, the outer leg 4o provided in the common magnetic body does not have to be shaped to surround the entire periphery of each inner leg 4i.

### Third Embodiment

The third embodiment describes, by way of example, a power supply module that differs from the power supply modules described in the first and second embodiments in the configurations of the common magnetic body and the opening.

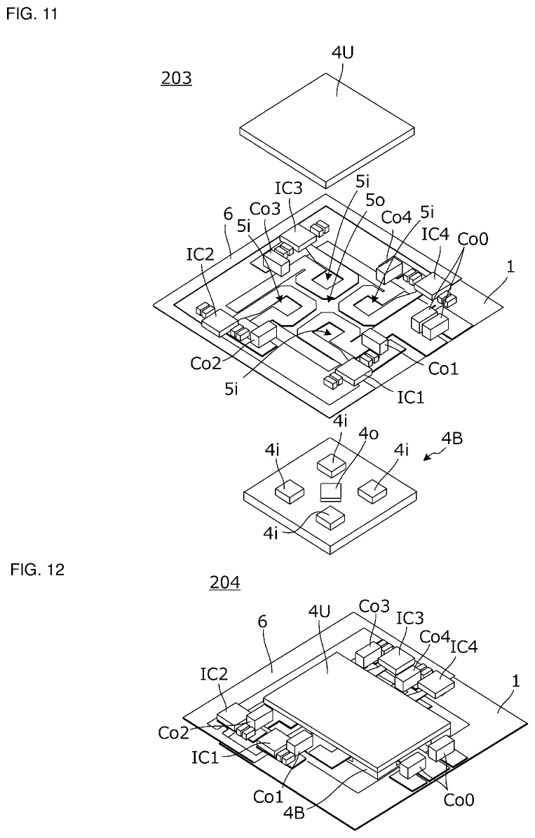

FIG. 11 is an exploded perspective view of a power supply module 203 according to the third embodiment. The power supply module 203 differs from the power supply module 202 illustrated in FIG. 10 in the second embodiment in the structures of the outer leg 4o of the common magnetic body.

In the example shown in FIG. 10, the outer leg 4o shielding between the inner legs 4i adjacent to each other is provided in the lower magnetic body 4B and the upper magnetic body 4U; however, in the third embodiment, an outer leg 4o is provided in a lower magnetic body 4B and an upper magnetic body 4U at a position surrounded by four inner legs 4i. Other configurations are the same as those illustrated in the second embodiment.

As described in the present embodiment, the outer leg 4o provided on the common magnetic body may be a single common outer leg formed at a position surrounded by each inner leg 4i.

### Fourth Embodiment

The fourth embodiment describes, by way of example, a power supply module in which an inductor of a smoothing filter is composed of a common wiring line and a common magnetic body.

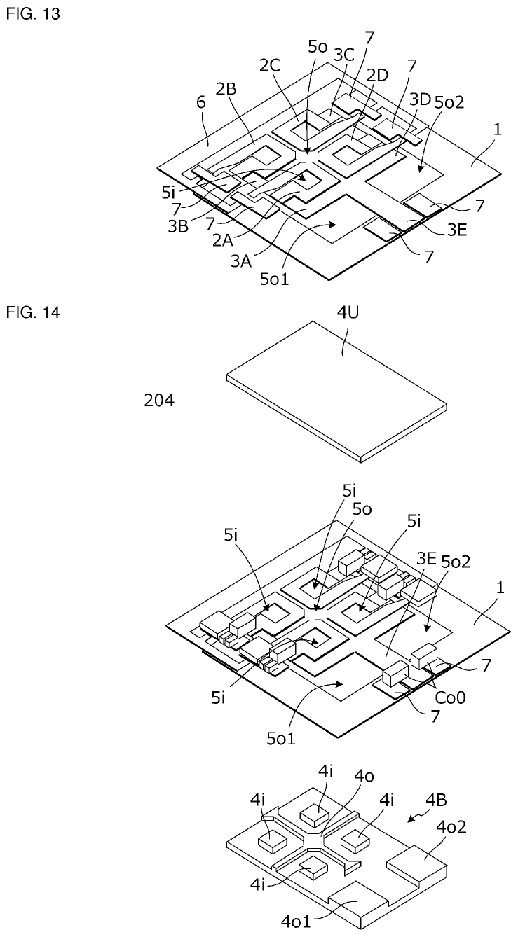

FIG. 12 is a perspective view of a power supply module 204 with a composite inductor according to the fourth embodiment. FIG. 13 is a perspective view of a circuit board of the power supply module 204. FIG. 14 is an exploded perspective view of the power supply module 204.

The power supply module 204 includes a circuit board 1, a plurality of components mounted on the circuit board 1, and a lower magnetic body 4B and an upper magnetic body 4U that are incorporated into the circuit board 1 from both sides. The lower magnetic body 4B and the upper magnetic body 4U constitute a “common magnetic body” according to the present disclosure.

As illustrated in FIG. 13, four inductor windings 2A, 2B, 2C, and 2D are formed in the circuit board 1. Further, common wiring lines 3A, 3B, 3C, 3D, and 3E are formed on the circuit board 1 to electrically connect one end of each of the plurality of inductor windings 2A, 2B, 2C, and 2D in common.

As illustrated in FIG. 14, in the circuit board 1, each of the inductor windings 2A, 2B, 2C, and 2D has an opening 5i formed thereinside. Further, the inductor windings 2A, 2B, 2C, and 2D have an opening 5o formed outside the inductor windings 2A, 2B, 2C, and 2D. Further, openings 5o1 and 5o2 are formed on both sides of the common wiring line 3E. The upper surface of the lower magnetic body 4B has inner legs 4i each inserted through a respective one of the openings 5i, an outer leg 4o inserted through the opening 5o, and outer legs 4o1 and 4o2 inserted through the openings 5o1 and 5o2, respectively.

The lower magnetic body 4B, the upper magnetic body 4U and the inductor windings 2A, 2B, 2C, and 2D constitute four inductors. Further, the lower magnetic body 4B, the upper magnetic body 4U and the common wiring line 3E constitute an inductor. The inductor windings 2A, 2B, 2C, and 2D are magnetically coupled to each other by the lower magnetic body 4B and the upper magnetic body 4U, and the inductor composed of the common wiring line 3E and the inductor windings 2A, 2B, 2C, and 2D are substantially not magnetically coupled.

The inductor windings 2A, 2B, 2C, and 2D are in a 180° rotational symmetry relationship along the surface of the circuit board 1, so that for each inductor the magnetic coupling relationship with the other inductors is equal. Such a configuration reduces the variation in inductance of each inductor.

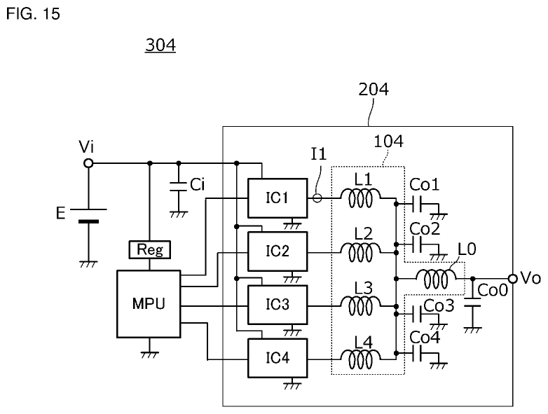

FIG. 15 is a circuit diagram of a multi-phase power supply device 304 according to the fourth embodiment. The multi-phase power supply device 304 is composed of the power supply module 204 and the control circuit for the power supply module 204. The power supply module 204 is mounted on a circuit board of an electronic device. The control circuit of the power supply module 204 is provided on the circuit board.

The multi-phase power supply device 304 connects an input power supply E with a voltage Vi to its input section and outputs an output voltage Vo from its output section.

The power supply module 204 includes switching integrated circuits IC1, IC2, IC3, and IC4, inductors L0, L1, L2, L3, and L4 and smoothing capacitors Co0, Co1, Co2, Co3, and Co4. The inductors L0, L1, L2, L3, and L4 are composed of a composite inductor 104. The inductors L1, L2, L3, and L4 are composed of the inductor windings 2A, 2B, 2C, and 2D, the lower magnetic body 4B, and the upper magnetic body 4U. The switching integrated circuits IC1, IC2, IC3, and IC4 each have a high-side switching element and a low-side switching element.

The inductor L0 is composed of the common wiring line 3E, the lower magnetic body 4B and the upper magnetic body 4U. The inductor L0 and the smoothing capacitors Co1, Co2, Co3, Co4, and Co0 constitute a π-type smoothing filter.

According to the present embodiment, since the inductor L0 can be configured with a predetermined inductance despite the short common wiring line 3E, the size of the area of the smoothing filter forming portion can be reduced. Further, since the line length of the common wiring line 3E can be reduced, the parasitic resistance can be reduced, and the attenuation in the attenuation region of the frequency characteristics of the smoothing filter can be increased.

Finally, the present disclosure is not limited to the above-described embodiments. Variations and modifications can be made as appropriate by those skilled in the art. The scope of the present disclosure is indicated not by the above-described embodiments but by the claims. Further, the scope of the present disclosure includes variations and modifications from the embodiments within a scope equivalent to the scope of the claims.

What is claimed is:

1. A switching power supply device comprising:
a plurality of power conversion circuits including a composite inductor; and
a control circuit for the power conversion circuits,
wherein
the composite inductor includes a circuit board on which a plurality of inductor windings is configured and a common magnetic body incorporated into the circuit board,
the circuit board has an electrical connection point with one end of each of the plurality of inductor windings as a common potential,
a common wiring line electrically connects the electrical connection point and one side of an output terminal,
the common magnetic body has inner legs each extending through inside a respective one of the plurality of inductor windings and an outer leg extending through outside the plurality of inductor windings,
a smoothing capacitor is electrically connected between one side of the output terminals and an other side of the output terminals and is mounted on the circuit board,
an inductance of the common wiring line and the smoothing capacitor configure a smoothing filter,
the plurality of inductor windings has a first magnetic coupling coefficient by the common magnetic body, and the common wiring line and the plurality of inductor windings have a second magnetic coupling coefficient, and
an absolute value of the first magnetic coupling coefficient is five or more times an absolute value of the second magnetic coupling coefficient.

2. The switching power supply device according to claim 1, wherein
the plurality of power conversion circuits each include a switching element, and
the control circuit is configured to cause the switching elements to switch with a phase of switching operation of the switching elements shifted.

3. The switching power supply device according to claim 1, wherein
the first magnetic coupling coefficient is equal to or less than 0.5.

4. The switching power supply device according to claim 1, wherein
the second magnetic coupling coefficient is less than 0.1.

5. The switching power supply device according to claim 1, wherein
the circuit board has an opening outside the common wiring line, the outer leg extending through the opening, and
the common wiring line and the common magnetic body configure an inductor of the smoothing filter.

6. The switching power supply device according to claim 1, wherein
the plurality of inductor windings is configured in a rotational symmetry relationship along a surface of the circuit board.

7. The switching power supply device according to claim 1, wherein
the circuit board is a multilayer board, and
the plurality of inductor windings each include a plurality of layers of conductor patterns in the circuit board and via conductors that interconnect the plurality of layers of conductor patterns.

8. The switching power supply device according to claim 1, further comprising:
a plurality of smoothing capacitors connected between the common wiring line and the common potential,
wherein the plurality of smoothing capacitors are in vicinity of respective connection portions between the common wiring line and the plurality of inductor windings.

9. The switching power supply device according to claim 1, wherein
the common magnetic body includes a lower magnetic body and an upper magnetic body incorporated into the circuit board from both sides, and
the lower magnetic body and the upper magnetic body closely contact each other with an adhesive layer having a relative permeability of 1 or higher or an adhesive layer containing magnetic powder interposed between the lower magnetic body and the upper magnetic body.

10. The switching power supply device according to claim 2, wherein
the first magnetic coupling coefficient is equal to or less than 0.5.

11. The switching power supply device according to claim 2, wherein
the second magnetic coupling coefficient is less than 0.1.

12. The switching power supply device according to claim 3, wherein
the second magnetic coupling coefficient is less than 0.1.

13. The switching power supply device according to claim 2, wherein
the circuit board has an opening outside the common wiring line, the outer leg extending through the opening, and
the common wiring line and the common magnetic body configure an inductor of the smoothing filter.

14. The switching power supply device according to claim 3, wherein
the circuit board has an opening outside the common wiring line, the outer leg extending through the opening, and
the common wiring line and the common magnetic body configure an inductor of the smoothing filter.

15. The switching power supply device according to claim 2, wherein
the plurality of inductor windings is configured in a rotational symmetry relationship along a surface of the circuit board.

16. The switching power supply device according to claim 3, wherein
the plurality of inductor windings is configured in a rotational symmetry relationship along a surface of the circuit board.

17. The switching power supply device according to claim 2, wherein
the circuit board is a multilayer board, and
the plurality of inductor windings each include a plurality of layers of conductor patterns in the circuit board and via conductors that interconnect the plurality of layers of conductor patterns.

18. The switching power supply device according to claim 3, wherein
the circuit board is a multilayer board, and
the plurality of inductor windings each include a plurality of layers of conductor patterns in the circuit board and via conductors that interconnect the plurality of layers of conductor patterns.

19. The switching power supply device according to claim 2, further comprising:
a plurality of smoothing capacitors connected between the common wiring line and the common potential,
wherein the plurality of smoothing capacitors are in vicinity of respective connection portions between the common wiring line and the plurality of inductor windings.

20. The switching power supply device according to claim 2, wherein
the common magnetic body includes a lower magnetic body and an upper magnetic body incorporated into the circuit board from both sides, and
the lower magnetic body and the upper magnetic body closely contact each other with an adhesive layer having a relative permeability of 1 or higher or an adhesive layer containing magnetic powder interposed between the lower magnetic body and the upper magnetic body.
